(19) United States
(12) Patent Application Publication
(10) Pub. No.: US 2025/0324585 A1
(43) Pub. Date: Oct. 16, 2025

(54) MEMORY DEVICE INCLUDING VERTICAL CHANNEL AND METHOD OF FORMING THE SAME

(71) Applicant: SK hynix Inc., Gyeonggi-do (KR)

(72) Inventor: Min Soo KIM, Gyeonggi-do (KR)

(21) Appl. No.: 18/892,554

(22) Filed: Sep. 23, 2024

(30) Foreign Application Priority Data
Apr. 12, 2024 (KR) 10-2024-0049016

(51) Int. Cl. H10B 41/27; H10B 41/35

(52) U.S. Cl. CPC H10B 41/27; H10B 41/35

(57) ABSTRACT

Embodiments of the present disclosure relate to a memory device which has a dual channel thickness, and a method of forming the same. The memory device includes a source plate; a stack structure including a plurality of interlayer insulating layers and a plurality of electrode layers which are alternately stacked on the source plate in a vertical direction; a through hole passing through the stack structure; a charge storage structure disposed on a sidewall of the through hole; and a channel pattern disposed on the charge storage structure, and including a first channel pattern which is adjacent to the source plate and a second channel pattern which is disposed on the first channel pattern in the vertical direction and has a width different from a width of the first channel pattern. It is possible to prevent deterioration of device characteristics due to a defect in processing.

### CROSS-REFERENCE TO RELATED APPLICATION

The present application claims priority under 35 U.S.C. § 119(a) to Korean Patent Application No. 10-2024-0049016 filed on Apr. 12, 2024, which is incorporated herein by reference in its entirety.

### BACKGROUND

### 1. Technical Field

Various embodiments of the present disclosure generally relate to semiconductor technology, and, more specifically, to a memory device and a method of forming the same.

### 2. Related Art

A three-dimensional memory device having memory cells which are three-dimensionally arranged has been proposed. The three-dimensional memory device has advantages in that a larger capacity may be realized within the same area by increasing the number of stacks through stacking memory cells in a vertical direction to highly integrate memory cells, thereby providing high performance and excellent power efficiency.

### SUMMARY

Various embodiments of the present disclosure are directed to a memory device comprising a vertical channel and a method of forming the same.

Various embodiments of the present disclosure are directed to a memory device and a method of forming the same, capable of preventing deterioration of device characteristics due to a defect in processing.

In an embodiment of the present disclosure, a memory device may include a source plate; a stack structure including a plurality of interlayer insulating layers and a plurality of electrode layers which are alternately stacked on the source plate in a vertical direction; a through hole passing through the stack structure; a charge storage structure disposed on a sidewall of the through hole; and a channel pattern disposed on the charge storage structure, and including a first channel pattern which is adjacent to the source plate and a second channel pattern which is disposed on the first channel pattern in the vertical direction and has a width different from a width of the first channel pattern.

In an embodiment of the present disclosure, a memory device may include a source plate; a stack structure including a plurality of interlayer insulating layers and a plurality of electrode layers which are alternately stacked on the source plate in a vertical direction; a through hole passing through the stack structure; a charge storage structure disposed on a sidewall of the through hole; a channel pattern disposed on the charge storage structure, and including a first channel pattern which is adjacent to the source plate and a second channel pattern which is disposed on the first channel pattern in the vertical direction; a first insulating layer disposed on a sidewall of the first channel pattern, and filling the through hole; and a second insulating layer disposed on a sidewall of the second channel pattern, filling the through hole, and having a width of at least a portion thereof smaller than a width of the first insulating layer.

In an embodiment of the present disclosure, a method of forming a memory device may include forming, on a substrate, a stack structure in which a plurality of interlayer insulating layers and a plurality of sacrificial layers are alternately stacked in a direction perpendicular to the substrate; forming a through hole which passes through the stack structure; forming a first channel pattern along a sidewall of the through hole; etching at least a portion of the first channel pattern; and forming a second channel pattern which has a width different from the first channel pattern, on the first channel pattern along a sidewall of the through hole in a vertical direction.

According to the embodiments of the present disclosure, it is possible to prevent device characteristics of memory cells from deteriorating due to a defect in processing.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a simplified block diagram illustrating a memory device according to an embodiment of the present disclosure.

FIG. 2 is an equivalent circuit diagram of a memory cell array illustrated in FIG. 1.

FIG. 3 is a view illustrating a cross-sectional structure of a memory device according to an embodiment of the present disclosure.

FIG. 4 is an enlarged view of a part A of FIG. 3.

FIG. 5 is a view illustrating an embodiment of the planar structure of the part A of FIG. 3.

FIGS. 6A and 6B are enlarged views of a part B of FIG. 4.

FIGS. 7 to FIG. 10 are views illustrating other cross-sectional structures of the memory device based on embodiments of the present disclosure.

FIGS. 11 to 25 are views illustrating a method of forming a memory device according to an embodiment of the present disclosure.

### DETAILED DESCRIPTION

Hereinafter, embodiments of the present disclosure will be described in detail with reference to the accompanying drawings.

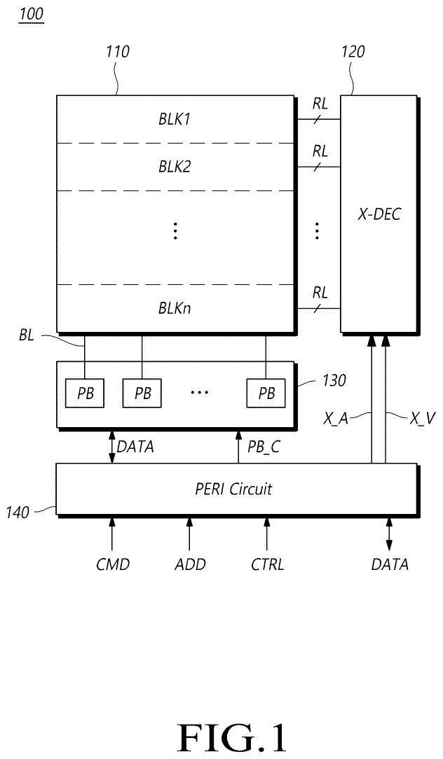

FIG. 1 is a simplified block diagram illustrating a memory device according to an embodiment of the present disclosure.

Referring to FIG. 1, the memory device 100 based on an embodiment of the present disclosure may include a memory cell array 110, a row decoder (X-DEC) 120, a page buffer circuit 130 and a peripheral circuit (PERI circuit) 140.

The memory cell array 110 may include a plurality of memory blocks BLK1 to BLKn, where n is a natural number of 2 or greater), each including a plurality of cell strings. Each of the cell strings may include at least one drain select transistor, a plurality of memory cells and at least one source select transistor coupled in series. The memory cells may be volatile or nonvolatile memory cells. The description below illustrates an embodiment employing the memory device 100 which is a vertical NAND flash device. However, it should be understood that the technical concepts of the present disclosure are not limited only to vertical NAND flash devices.

The row decoder 120 may be coupled to the memory cell array 110 through a plurality of row lines RL which may include at least one drain select line, a plurality of word lines, and at least one source select line.

In operation the row decoder 120 may select a memory block among the plurality of memory blocks BLK1 to BLKn of the memory cell array 110, in response to a row address X_A received from the peripheral circuit 140. The row decoder 120 may then transmit an operating voltage X_V received from the peripheral circuit 140, to the row lines RL coupled to the selected memory block.

The memory cell array 110 may be coupled to the page buffer circuit 130 through a plurality of bit lines BL. The page buffer circuit 130 may include a plurality of page buffers PB coupled to corresponding bit lines BL. The page buffer circuit 130 may receive a page buffer control signal PB_C from the peripheral circuit 140 and may transmit and receive a data signal DATA to and from the peripheral circuit 140.

The page buffer circuit 130 may control a bit line BL arranged in the memory cell array 110, in response to the page buffer control signal PB_C. For example, the page buffer circuit 130 may detect data, stored in a memory cell of the memory cell array 110, by sensing the signal of a bit line BL of the memory cell array 110 in response to the page buffer control signal PB_C, and may transmit the data signal DATA to the peripheral circuit 140 according to the detected data. The page buffer circuit 130 may apply a signal to a bit line BL based on the data signal DATA, received from the peripheral circuit 140, in response to the page buffer control signal PB_C, and accordingly, may write data to a memory cell of the memory cell array 110. The page buffer circuit 130 may write or read data to or from a memory cell which is coupled to a word line activated by the row decoder 120.

The peripheral circuit 140 may receive a command signal CMD, an address signal ADD and a control signal CTRL from outside the memory device 100 and may transmit and receive data DATA to and from a device outside the memory device 100, for example, a memory controller. The peripheral circuit 140 may output signals for writing data to the memory cell array 110 or reading data from the memory cell array 110, for example, the row address X_A, the page buffer control signal PB_C, a source line discharge control signal SLD_C and so forth, based on the command signal CMD, the address signal ADD and the control signal CTRL. The peripheral circuit 140 may generate various voltages including the operating voltage X_V, which are required in the memory device 100.

In the accompanying drawings, two directions that are parallel to the upper surface of a substrate are defined as a first direction FD and a second direction SD, respectively, and a direction that vertically protrudes from the upper surface of the substrate is defined as a third direction VD. For example, the first direction FD may correspond to the extending direction of word lines, and the second direction SD may correspond to the extending direction of bit lines. The first direction FD and the second direction SD may be substantially perpendicular to each other. The third direction VD may be a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto indicate the same direction.

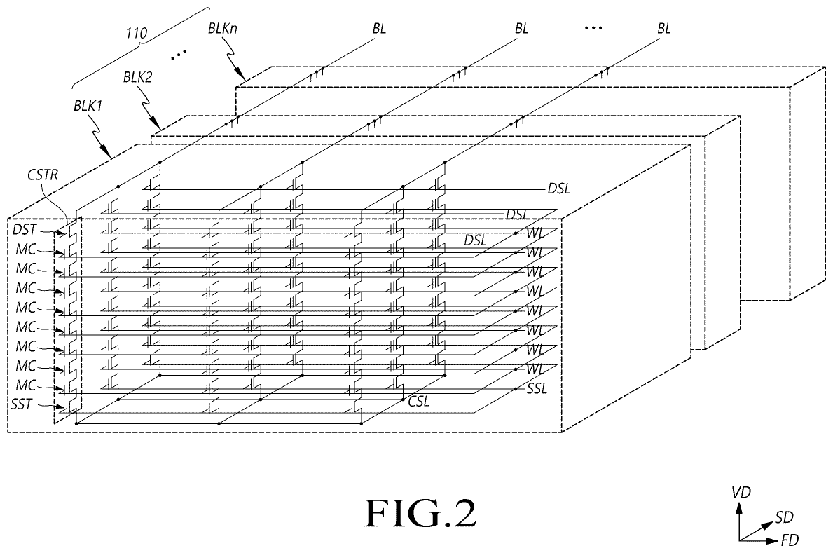

FIG. 2 is an equivalent circuit diagram of the memory cell array 110 of FIG. 1.

Referring now to FIG. 2, each of the memory blocks BLK1 to BLKn may include a plurality of cell strings CSTR coupled between a plurality of bit lines BL and a common source line CSL.

The bit lines BL may extend in the second direction SD and may be arranged in the first direction FD. A plurality of cell strings CSTR may be coupled in parallel to each of the bit lines BL. The cell strings CSTR may be coupled in common to the common source line CSL. The plurality of cell strings CSTR may be disposed between the plurality of bit lines BL and the one common source line CSL.

Each of the cell strings CSTR may include a drain select transistor DST which is coupled to a bit line BL, a source select transistor SST which is coupled to the common source line CSL, and a plurality of memory cells MC which are coupled between the drain select transistor DST and the source select transistor SST. The drain select transistor DST, the memory cells MC and the source select transistor SST may be coupled in series in the third direction VD.

Drain select lines DSL, a plurality of word lines WL and a source select line SSL may be disposed between the bit lines BL and the common source line CSL in the third direction VD. Each of the drain select lines DSL may be coupled to the gates of corresponding drain select transistors DST. Each of the word lines WL may be coupled to the gates of corresponding memory cells MC. The source select line SSL may be coupled to the gates of source select transistors SST. Memory cells MC which are coupled in common to one word line WL may constitute one page.

The bit lines BL and the common source line CSL may be coupled in common to the memory blocks BLK1 to BLKn. That is, the memory blocks BLK1 to BLKn may share the bit lines BL and the common source line CSL. The drain select lines DSL, the plurality of word lines WL, and the source select line SSL may be provided to each of the memory blocks BLK1 to BLKn.

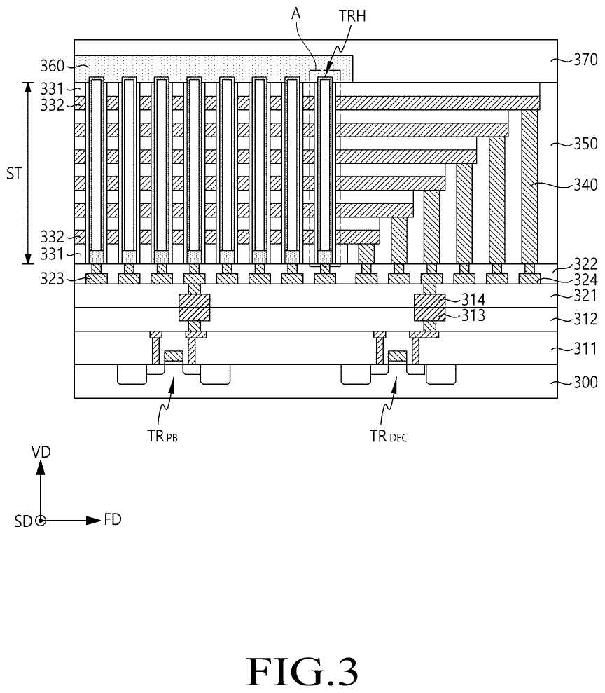

FIG. 3 is a view illustrating across-sectional structure of a memory device according to an embodiment of the present disclosure.

Referring to FIG. 3, the memory device based on the illustrated embodiment may include a substrate 300. The substrate 300 may include any suitable semiconductor substrate such as, for example, a silicon wafer or an SOI (silicon on insulator) wafer. The substrate 300 may include a III-V group semiconductor substrate, for example, a compound semiconductor substrate such as GaAs. The substrate 300 may include monocrystalline silicon, polysilicon, amorphous silicon, monocrystalline silicon germanium, polycrystalline silicon germanium, carbon-doped silicon, or a combination thereof.

A circuit insulating layer 311 may be disposed on the substrate 300 and may include a single layer or a multilayer structure. The circuit insulating layer 311 may include silicon oxide, silicon nitride, silicon oxynitride, silicon carbonitride (SiCN), silicon oxycarbonitride (SiOCN), low-k dielectric, high-k dielectric, or a combination thereof.

A first transistor TR_{PB} and a second transistor TR_{DEC} may be disposed in the substrate 300 and the circuit insulating layer 311. The first transistor TR_{PB} may be a page buffer PB, and the second transistor TR_{DEC} may be a pass transistor which is included in the row decoder 120.

A first insulating bonding layer312 may be disposed on the circuit insulating layer 311. The first insulating bonding layer 312 may include silicon oxide, silicon nitride, silicon oxynitride, silicon carbonitride (SiCN), silicon oxycarbonitride (SiOCN), low-k dielectric, high-k dielectric, or a combination thereof. In an embodiment, the first insulating bonding layer 312 may include silicon carbonitride (SiCN). A plurality of first bonding pads 313 may be disposed in the

first insulating bonding layer 312. The plurality of first bonding pads 313 may include metal, metal nitride, metal oxide, metal silicide, polysilicon, conductive carbon, or a combination thereof. Each of the plurality of first bonding pads 313 may be electrically connected to a corresponding at least one of the first and second transistors TR_{PB} and TR_{DEC}. The upper surfaces of the first insulating bonding layer 312 and the plurality of first bonding pads 313 may form substantially the same plane.

A second insulating bonding layer 321 may be disposed on the first insulating bonding 312. The second insulating bonding layer 321 may include silicon oxide, silicon nitride, silicon oxynitride, silicon carbonitride (SiCN), silicon oxycarbonitride (SiOCN), low-k dielectric, high-k dielectric, or a combination thereof. The second insulating bonding layer 321 may include a material similar to that of the first insulating bonding layer 312. In an embodiment, the second insulating bonding layer 321 may include silicon carbonitride (SiCN).

A plurality of second bonding pads 314 may be disposed in the second insulating bonding layer 321. The plurality of second bonding pads 314 may include metal, metal nitride, metal oxide, metal silicide, polysilicon, conductive carbon, or a combination thereof. The plurality of second bonding pads 314 may include a material similar to that of the plurality of first bonding pads 313. The upper surfaces of the second insulating bonding layer 321 and of the plurality of second bonding pads 314 may be aligned substantially on the same plane.

An insulating layer 322 may be disposed on the second insulating bonding layer 321. The insulating layer 322 may include silicon oxide, silicon nitride, silicon oxynitride, silicon carbonitride (SiCN), silicon oxycarbonitride (SiOCN), low-k dielectric, high-k dielectric, or a combination thereof. A plurality of interconnections 323 and 324 may be disposed in the insulating layer 322. The plurality of interconnections 323 and 324 may include first interconnections 323 and second interconnections 324. Each of the plurality of interconnections 323 and 324 may be electrically connected to a corresponding at least one of the plurality of second bonding pads 314.

A stack structure ST may be disposed on the insulating layer 322. The stack structure ST may include a plurality of alternating interlayer insulating layers 331 and electrode layers 332 stacked in the third direction VD. Each of the uppermost and lowermost layers of the stack structure ST may be an interlayer insulating layer 331. The plurality of interlayer insulating layers 331 may include silicon oxide, silicon nitride, silicon oxynitride, silicon carbonitride (SiCN), silicon oxycarbonitride (SiOCN), low-k dielectric, high-k dielectric, or a combination thereof. The plurality of electrode layers 332 may include Cu, Al, Ni, Co, Ru, W, WN, Ti, TiN, Ta, TaN, Sn, Pt, Au, Ag, or a combination thereof.

The plurality of interlayer insulating layers 331 and the plurality of electrode layers 332 may include a stairway structure. A buried insulating layer 350 may be disposed on the plurality of interlayer insulating layers 331 and the plurality of electrode layers 332 which have the stairway structure. The buried insulating layer 350 may include silicon oxide, silicon nitride, silicon oxynitride, silicon carbonitride (SiCN), silicon oxycarbonitride (SiOCN), low-k dielectric, high-k dielectric, or a combination thereof.

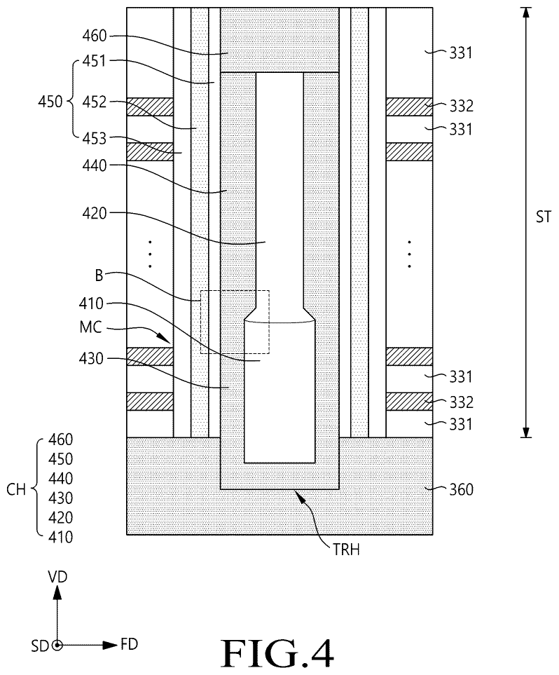

The stack structure ST may include a plurality of through holes TRH which pass through the plurality of interlayer insulating layers 331 and the plurality of electrode layers 332 in the third direction VD. A channel structure including an information storage structure, a channel pattern, a plurality of insulating layers and a drain pad may be disposed in the through hole TRH. The detailed structure of the channel structure will be described later with reference to FIG. 4.

The channel structure in the through hole TRH which passes through the stack structure ST may be connected to the first transistor TR_{PB} via a corresponding first interconnection 323, a corresponding second bonding pad 314, and a corresponding first bonding pad 313.

The plurality of electrode layers 332 included in the stack structure ST may extend in the first direction FD. Each of the plurality of electrode layers 332 which extend in the first direction FD may be connected to the second transistor TR_{DEC} via a corresponding one of a plurality of contact plugs 340, a corresponding one of the plurality of second interconnections 324, a corresponding one of the plurality of second bonding pads 314 and a corresponding one of the plurality of first bonding pads 313.

A source plate 360 and an upper insulating layer 370 may be disposed on the stack structure ST. The source plate 360 may include a semiconductor material such as polysilicon. The source plate 360 may be connected to the common source line CSL.

The through hole TRH may extend into the source plate 360 by passing through the stack structure ST. The upper surface of the through hole TRH may be located higher than the upper surface of the stack structure ST.

The upper insulating layer 370 may cover the stack structure ST and the source plate 360. The upper insulating layer 370 may include silicon oxide, silicon nitride, silicon oxynitride, silicon carbonitride (SiCN), silicon oxycarbonitride (SiOCN), low-k dielectric, high-k dielectric, or a combination thereof.

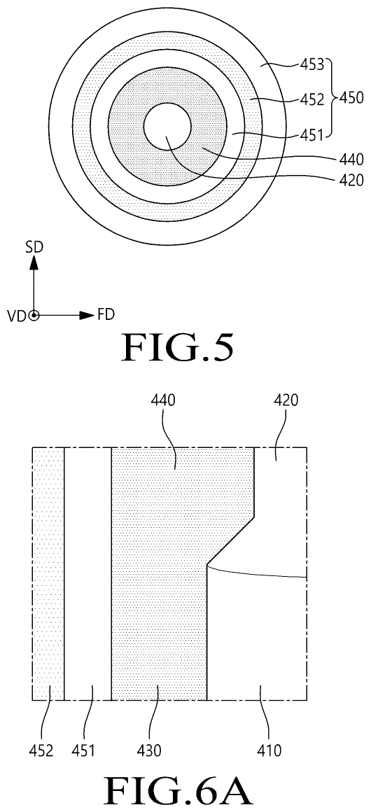

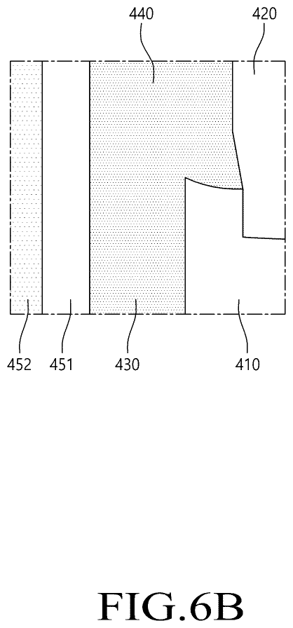

FIG. 4 is an enlarged view of part A of FIG. 3. FIG. 5 is a view illustrating an example of the planar structure of part A of FIG. 3. FIGS. 6A and 6B are enlarged views of a part B of FIG. 4.

Referring to FIGS. 4, 5 and 6A, a channel structure CH may be disposed in the through hole TRH which passes through the stack structure ST. The channel structure CH may include a first insulating layer 410, a second insulating layer 420, a first channel pattern 430, a second channel pattern 440, an information storage structure 450, and a drain pad 460. The information storage structure 450 may include a tunnel layer 451, a charge trap layer 452, and a blocking layer 453. The channel structure CH may extend into the source plate 360 by passing through the stack structure ST.

The information storage structure 450 may be disposed along a sidewall of the through hole TRH. Specifically, the blocking layer 453 may be disposed on the sidewall of the through hole TRH. A side surface of the blocking layer 453 may contact the sidewall of the through hole

TRH, that is, the plurality of the electrode layers 332 and the plurality the interlayer insulating layers 331 of the stack structure ST. The blocking layer 453 may include aluminum oxide (Al2O3).

The charge trap layer 452 may be disposed on the other side surface of the blocking layer 453. The blocking layer 453 may surround the charge trap layer 452. A side surface of the charge trap layer 452 may contact the blocking layer 453. In an embodiment, the charge trap layer 452 may include silicon nitride. The charge trap layer 452 may include a material with an energy barrier lower than the tunnel layer 451. In an embodiment, the tunnel layer 451 may include silicon oxide, silicon nitride, aluminum oxide (Al2O3), magnesium oxide (MgO) or zirconium oxide (ZrO2).

The tunnel layer 451 may be disposed on the other side surface of the charge trap layer 452. The charge trap layer 452 may surround the tunnel layer 451. A side surface of the tunnel layer 451 may contact the charge trap layer 452.

The first channel pattern 430, the second channel pattern 440 and the drain pad 460 may be disposed on the other side (for example, inner side) surface of the tunnel layer 451. The tunnel layer 451 may surround at least a portion of the first channel pattern 430, the second channel pattern 440 and the drain pad 460. The first channel pattern 430, the second channel pattern 440 and the drain pad 460 may include a semiconductor material such as polysilicon. The drain pad 460 may cover the top surfaces of the second insulating layer 420 and of the second channel pattern 440.

A side surface (for example, an outer side surface) of the first channel pattern 430 may contact the tunnel layer 451 and the sidewall of the through hole TRH. A lower part of the side surface (for example, the outer side surface} of the first channel pattern 430 may also contact the source plate 360. The first channel pattern 430 may partially cover a portion of the through hole TRH which extends into the source plate 360. Namely, the first channel pattern 430 may contact one surface of the source plate 360 which is perpendicular to the third direction VD, among the surfaces of the source plate 360.

The first channel pattern 430 may have an overall U shape with the lower part extending inside the source plate 360.

A side surface (for example, an outer side surface) of the second channel pattern 440 may contact the tunnel layer 451. One end of the second channel pattern 440 may contact the drain pad 460. The other end of the second channel pattern 440 may contact the first channel pattern 430.

The side surface of the drain pad 460 may contact the tunnel layer 451. In addition, one surface of the drain pad 460 which is perpendicular to the third direction VD may contact the second channel pattern 440.

The first insulating layer 410 and the second insulating layer 420 may be disposed on the other side surfaces of the first channel pattern 430 and the second channel pattern 440. The first insulating layer 410 and the second insulating layer 420 may include silicon oxide, silicon nitride, silicon oxynitride, polysilicon, or a combination thereof. The first channel pattern 430, the second channel pattern 440 and the drain pad 460 may surround the first insulating layer 410 and the second insulating layer 420.

In the embodiment according to the present disclosure, the width of the first channel pattern 430 in the first direction FD may be smaller than the width of the second channel pattern 440 in the first direction FD. In an embodiment, the width of the first channel pattern 430 in the first direction FD may be 5 to 10 nm, and the width of the second channel pattern 440 in the first direction FD may be 7.5 to 12 nm. However, the embodiments are not limited thereto. Since the width of the first channel pattern 430 in the first direction FD is different from the width of the second channel pattern 440 in the first direction FD, a step may be formed at the boundary between the first channel pattern 430 and the second channel pattern 440.

The first channel pattern 430 may be continuous to the second channel pattern 440. The length of the first channel pattern 430 in the third direction VD may be smaller than the length of the second channel pattern 440 in the third direction VD. In an embodiment, the length of the first channel pattern 430 in the third direction VD may be equal to or smaller than ⅓ of the length of the second channel pattern 440 in the third direction VD.

The first insulating layer 410 may be disposed on the other side surface of the first channel pattern 430. The first insulating layer 410 may overlap with the first channel pattern 430 in the first direction FD. The second insulating layer 420 may be disposed on the other side surface of the second channel pattern 440. The second insulating layer 420 may overlap with the second channel pattern 440 in the first direction FD. The first insulating layer 410 and the second insulating layer 420 may fill the inside of the through hole TRH. In an embodiment, a material of which the first insulating layer 410 is made may be different from a material of which the second insulating layer 420 is made.

The side surface of the first insulating layer 410 and the surface of the first insulating layer 410 adjacent to the source plate 360 may contact the first channel pattern 430.

In an embodiment, among the surfaces of the first insulating layer 410, the surface perpendicular to the third direction VD may be located at a different level in the third direction VD from a surface of the source plate 360 which contacts the information storage structure 450. That is, the first insulating layer 410 may fill a portion where the through hole TRH extends into the source plate 360.

As the width of the first channel pattern 430 in the first direction FD is formed to be smaller than the width of the second channel pattern 440 in the first direction FD, the diameter of the first insulating layer 410 which fills the through hole TRH may be larger than the diameter of the second insulating layer 420. However, the embodiments are not necessarily limited thereto.

The plurality of electrode layers 332 may include a plurality of word lines and a plurality of select lines. Memory cells MC may be formed at intersections of the channel structure CH and the plurality of word lines. Among the plurality electrode layer 332, at least one adjacent to the source plate 360 may correspond to a source select line. Among the plurality of electrode layers 332, at least one adjacent to the drain pad 460 may correspond to a drain select line. The plurality of word lines may be disposed between the at least one drain select line and the at least one source select line among the plurality of electrode layers 332.

Referring to FIG. 6B, in an embodiment, the first insulating layer 410 may have a structure in which at least a portion of the first insulating layer 410 is recessed in the third direction VD. The second insulating layer 420 may fill the recessed portion of the first insulating layer 410. The first insulating layer 410 may surround at least a portion of the second insulating layer 420.

The upper surface of the first insulating layer 410 may contact the second channel pattern 440 and the second insulating layer 420.

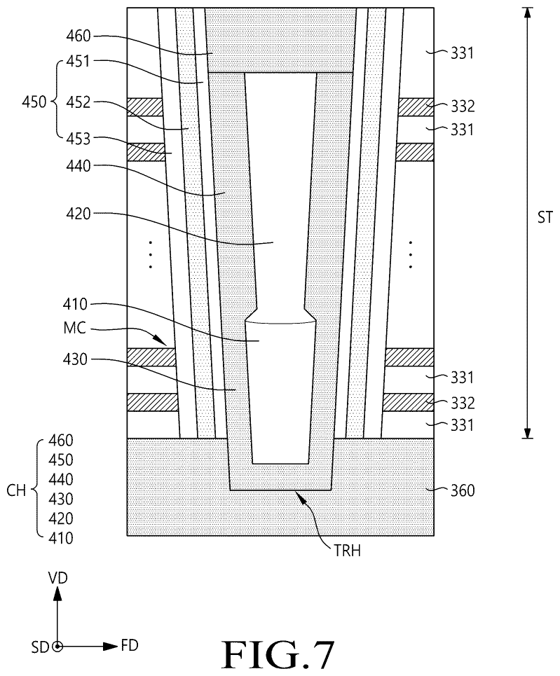

The first insulating layer 410 may contact the second insulating layer 420 in a recessed area and may contact the second channel pattern 440 in a non-recessed area. A portion of the upper surface of the first insulating layer 410 which contacts the second insulating layer 420 may be formed at a different level from a portion of the upper surface of the first insulating layer 410 which contacts the second channel pattern 440. FIGS. 7 to FIG. 10 are views illustrating other cross-sectional structures of the memory device based on the embodiments of the present disclosure.

In the following description of embodiments, description of components which are substantially the same as or correspond to those of the previous embodiments will be omitted.

Referring to FIG. 7, in an embodiment, the sidewall of the through hole TRH may form a predetermined angle with the upper surface of the source plate 360. The diameter of the through hole TRH in an area adjacent to the source plate 360 may be smaller than the diameter of the through hole TRH in an area adjacent to the drain pad 460. The diameter of the through hole TRH may gradually increase from the source plate 360 to the drain pad 460 in the third direction VD.

The width of the first channel pattern 430 in the first direction FD may be smaller than the width of the second channel pattern 440 in the first direction FD. As the width of the first channel pattern 430 in the first direction FD is formed to be smaller than the width of the second channel pattern 440 in the first direction FD, the diameter of at least a portion of the first insulating layer 410 which is disposed on the sidewall of the first channel pattern 430 and fills the through hole TRH may be larger than the diameter of at least a portion of the second insulating layer 420 which is disposed on the sidewall of the second channel pattern 440 and fills the through hole TRH.

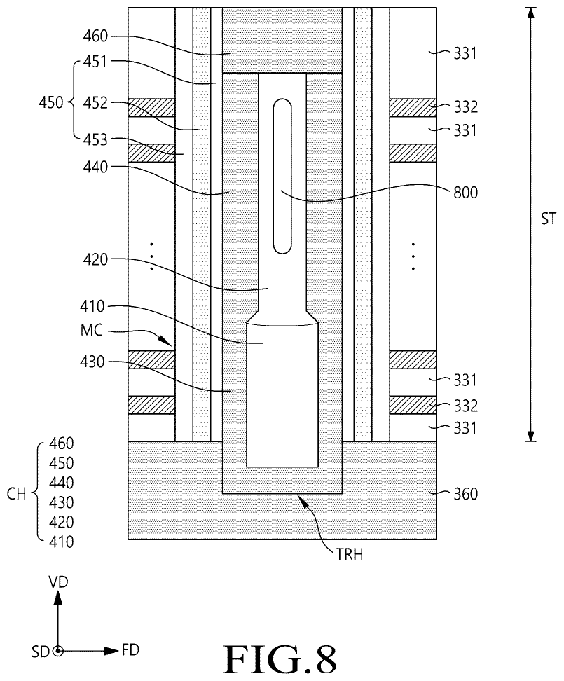

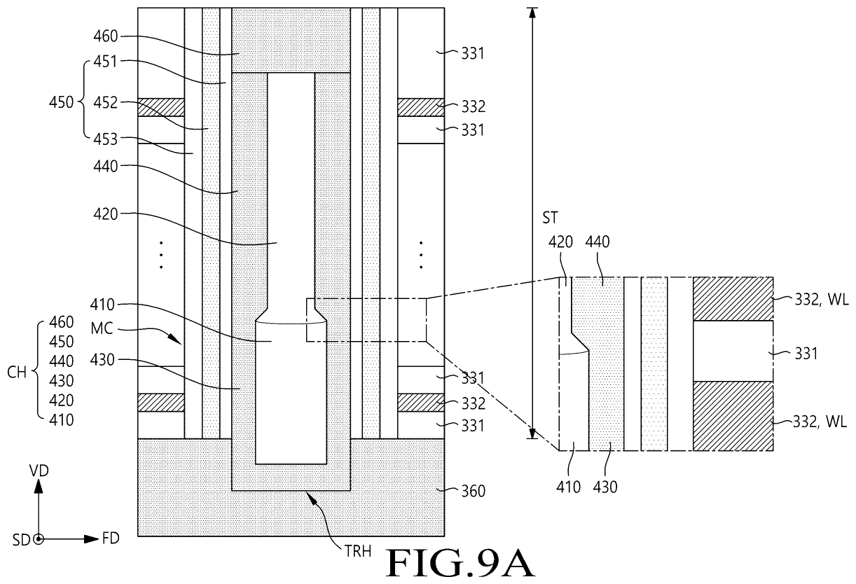

Referring to FIG. 8, at least a portion of the second insulating layer 420 may include a void 800 therein. The void 800 may extend in the third direction VD, but the embodiments are not necessarily limited thereto. The void 800 may be formed to be spaced apart from the first insulating layer 410, but the embodiments are not limited thereto. The memory device illustrated in FIG. 8 may be substantially the same as the memory device illustrated in FIG. 4 except that the second insulating layer 420 includes a void 800.

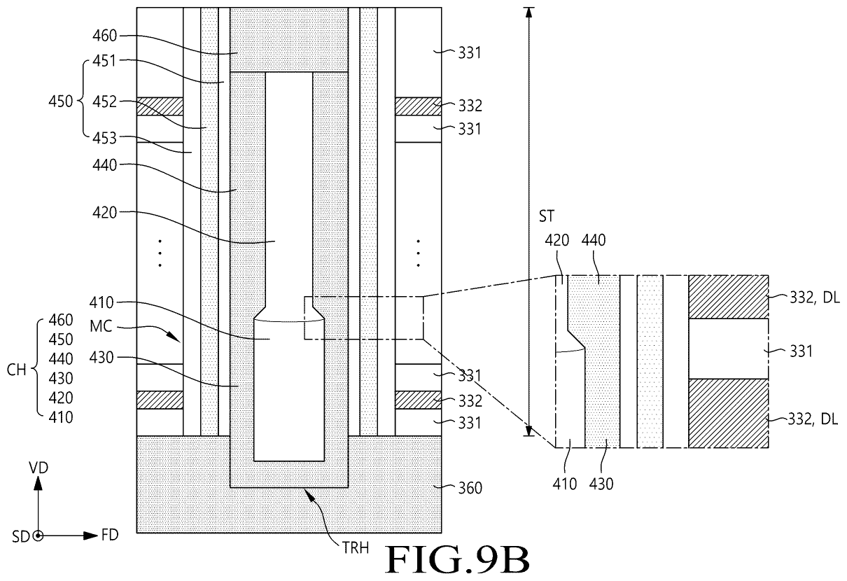

Referring to FIGS. 9A and 9B, at least one dummy electrode line DL may be disposed between a source select line SSL and a word line WL. The at least one dummy electrode line DL may overlap at least one of the first channel pattern 430 and the second channel pattern 440 in the first direction FD.

Referring to FIG. 9A, the word line WL adjacent to the at least one dummy electrode line DL may overlap with the first channel pattern 430 in the first direction FD. At least one word line WL may be disposed between the boundary of the first channel pattern 430 and the second channel pattern 440 and the source plate 360. In this case, the at least one dummy electrode line DL may overlap only the first channel pattern 430 in the first direction FD. The remaining word lines WL except the word line WL which overlaps the first channel pattern 430 in the first direction FD may overlap with the second channel pattern 440 in the first direction FD.

Although not illustrated, a drain select line DSL may overlap with the second channel pattern 440 in the first direction FD in an area adjacent to the drain pad 460.

Referring to FIG. 9B, one or more dummy electrode lines DL may overlap with the first channel pattern 430 and the second channel pattern 440 in the first direction FD. In this case, the plurality of word lines WL may overlap only the second channel pattern 440 in the first direction FD. Namely, the plurality of word lines WL may not overlap with the first channel pattern 430 in the first direction FD. The plurality of word lines WL may be disposed between the boundary of the first channel pattern 430 and the second channel pattern 440 and the drain pad 460.

Although not illustrated, a drain select line DSL may overlap with the second channel pattern 440 in the first direction FD in an area adjacent to the drain pad 460.

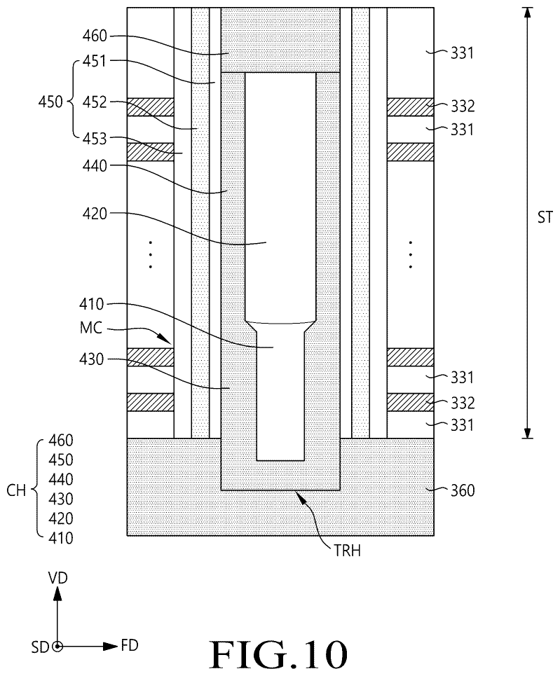

Although not illustrated, in an embodiment, at least one dummy electrode line DL may overlap only the second channel pattern 440 in the first direction FD. In this case, the first channel pattern 430 may overlap only a source select line SSL in the first direction FD. Referring to FIG. 10, in an embodiment, the width of the first

channel pattern 430 in the first direction FD may be larger than the width of the second channel pattern 440 in the first direction FD. The first channel pattern 430 may be continuous to the second channel pattern 440. The length of the first channel pattern 430 in the third direction VD may be smaller than the length of the second channel pattern 440 in the third direction VD. In an embodiment, the length of the first channel pattern 430 in the third direction VD may be equal to or smaller than 1/3 of the length of the second channel pattern 440 in the third direction VD. The first channel pattern 430 may extend inside the source plate 360 and may also surround the side and bottom surfaces of the first insulating layer 410.

The first insulating layer 410 may be disposed on the side surface (for example, inner side surface) of the first channel pattern 430 and also on the inner bottom surface of the first channel pattern 430. The first insulating layer 410 may overlap with the first channel pattern 430 in the first direction FD. The second insulating layer 420 may be disposed on the side surface of the second channel pattern 440. The second insulating layer 420 may overlap with the second channel pattern 440 in the first direction FD. The first insulating layer 410 and the second insulating layer 420 may fill the inside of the through hole TRH with the first insulating layer 410 positioned below the second insulating layer 420. In an embodiment, a material of which the first insulating layer 410 is made may be different from a material of which the second insulating layer 420 is made.

One surface (for example, a top surface) of the first insulating layer 410 may contact the second insulating layer 420. The other surface (for example, the bottom surface) of the first insulating layer 410, that is, a surface of the first insulating layer 410 adjacent to the source plate 360, may contact the first channel pattern 430 (for example, the inner bottom surface of the first channel pattern 430).

In an embodiment, the other surface of the first insulating layer 410 may be located at a different level in the third direction VD from a surface of the source plate 360 which contacts the information storage structure 450. That is, the first insulating layer 410 may fill a portion of the through hole TRH which extends into the source plate 360.

As the width of the first channel pattern 430 in the first direction FD is formed to be larger than the width of the second channel pattern 440 in the first direction FD, the diameter of the first insulating layer 410 which fills the through hole TRH may be smaller than the diameter of the second insulating layer 420.

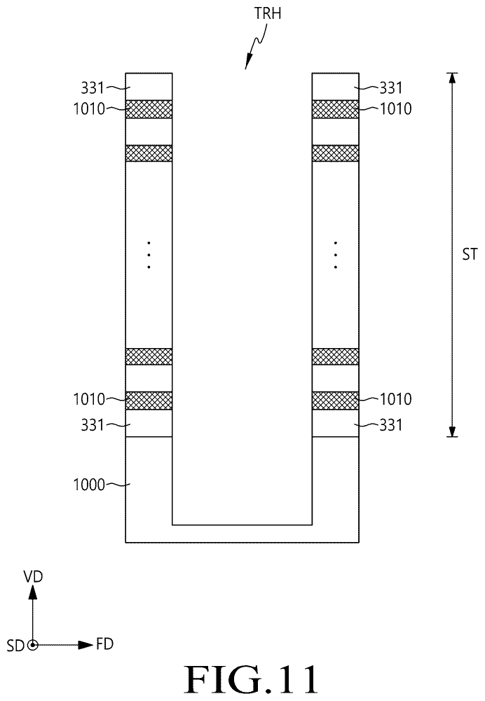

FIGS. 11 to 25 are views illustrating a method of forming a memory device according to an embodiment of the present disclosure.

Referring to FIG. 11, a stack structure ST having a plurality of alternately stacked interlayer insulating layers 331 and first sacrificial layers 1010 may be formed on a substrate 1000. At least one through hole TRH may be formed to pass through the stack structure and extend into the substrate 1000 to a predetermined depth.

The plurality of the first sacrificial layers 1010 may include a material which has an etch selectivity with respect to the plurality of the interlayer insulating layers 331. In an embodiment, the plurality of the first sacrificial layers 1010 may include nitride such as silicon nitride. The lowermost layer of the stack structure ST may be one of the plurality of interlayer insulating layers 331, and the uppermost layer of the stack structure ST may be one of the plurality of interlayer insulating layers 331.

A stack structure in which a plurality of interlayer insulating layers and a plurality of sacrificial layers are alternately stacked may be formed on the stack structure ST which includes the through hole TRH, and a through hole which passes through the additionally formed stack structure may be additionally formed. However, in describing the following drawings, a case where one stack structure is formed and a through hole is formed to pass through the one stack structure will be described as an example.

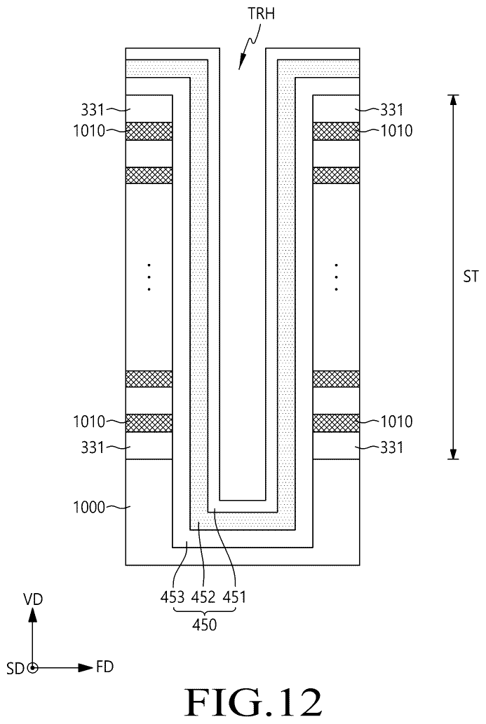

Referring to FIG. 12, an information storage structure 450 may be formed on the sidewall of the through hole TRH. The information storage structure 450 may be formed conformally to cover the entire surface of the through hole TRH. The information storage structure 450 may include a blocking layer 453, a charge trap layer 452, and a tunnel layer 451. The information storage structure 450 may be disposed to cover the sidewall of the through hole TRH and one surface of the substrate 1000 which is perpendicular to the third direction VD.

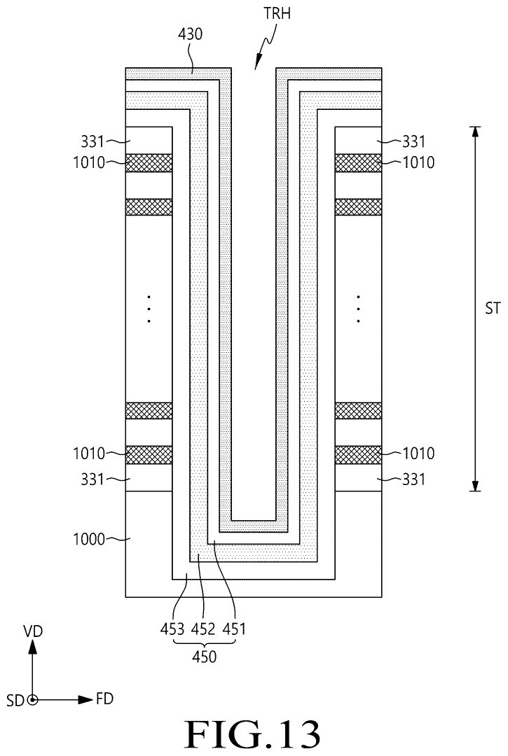

Referring to FIG. 13, a first channel pattern 430 may be formed conformally on the sidewall of the information storage structure 450. In an embodiment, the width of the first channel pattern 430 in the first direction FD may be 5 nm to 10 nm. The first channel pattern 430 may be disposed to cover the sidewall of the information storage structure 450 and a surface of the information storage structure 450 which is perpendicular to the third direction VD.

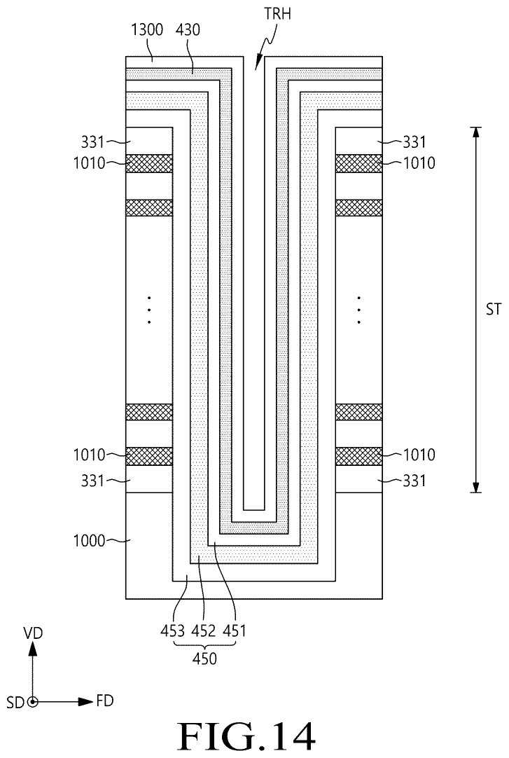

Referring to FIG. 14, a second sacrificial layer 1300 may be formed conformally on the sidewall of the first channel pattern 430. The second sacrificial layer 1300 may include silicon oxide, silicon nitride, silicon oxynitride, polysilicon, or a combination thereof. The second sacrificial layer 1300 may surround the first channel pattern 430.

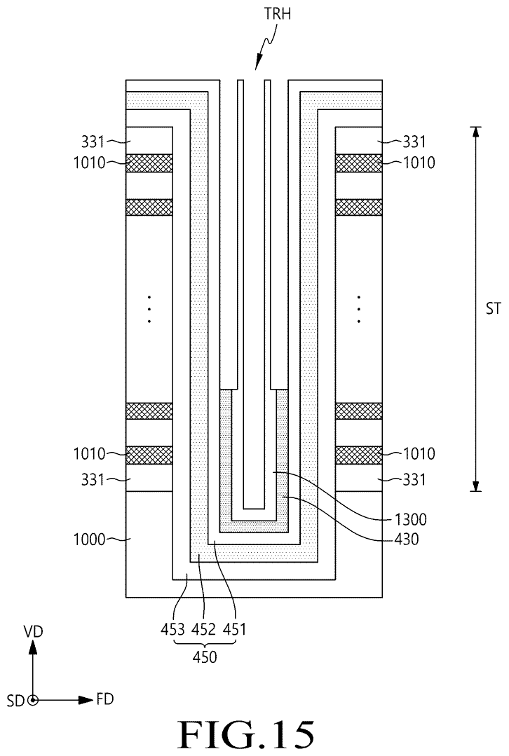

Referring to FIG. 15, a portion of the second sacrificial layer 1300 may be removed, for example, via a chemical mechanical polishing (CMP) process. As the upper portion of the second sacrificial layer 1300 is removed, a portion of the first channel pattern 430 may be exposed.

The first channel pattern 430 may include a material which has an etch selectivity with respect to the second sacrificial layer 1300. The exposed first channel pattern 430 may be removed through a wet etching process. At least a portion of the first channel pattern 430 which is disposed on the sidewall of the information storage structure 450 may be removed. The length in the third direction VD of the first channel pattern 430 which remains by not being removed may be smaller than the length of the removed first channel pattern 430 in the third direction VD. In an embodiment, the length in the third direction VD of the first channel pattern 430 which remains by not being removed may be equal to or smaller than ⅓ of the length of the removed first channel pattern 430 in the third direction VD.

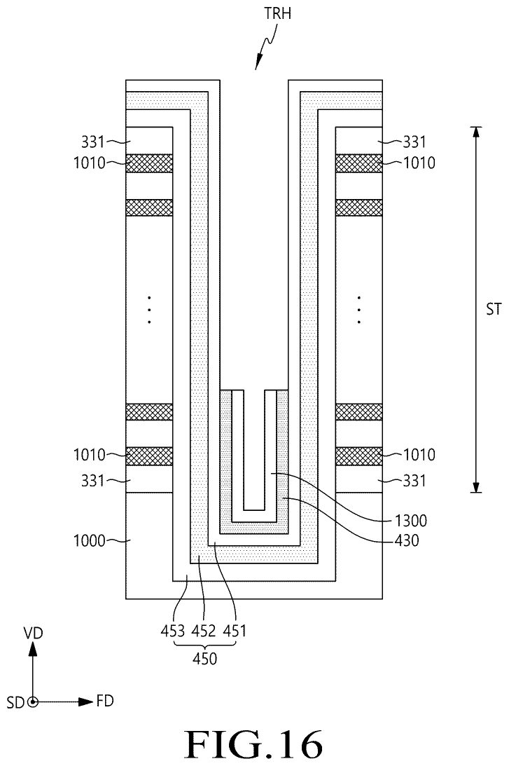

Referring to FIG. 16, a portion of the second sacrificial layer 1300 may be removed, for example, via a wet etching process. The length in the third direction VD of the second sacrificial layer 1300 which remains by not being removed may be substantially the same as the length of the remaining first channel pattern 430 in the third direction VD. Here, being substantially the same may include not only a case where the two lengths are completely the same but also a case where there is a fine difference approximately caused due to a process error.

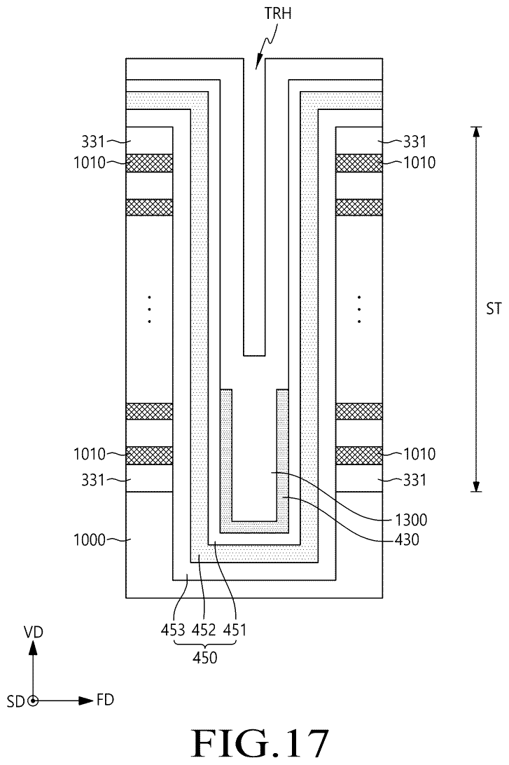

Referring to FIG. 17, a second sacrificial layer 1300 may be further formed to fill at least a portion of the inside of the through hole TRH. The second sacrificial layer 1300 may be formed on the first channel pattern 430 and the sidewall of the information storage structure 450. In an embodiment, the second sacrificial layer 1300 may fill the through hole TRH to a level higher in the third direction VD than an area where the first channel pattern 430 is formed. In another embodiment, the second sacrificial layer 1300 may completely fill the inside of the through hole TRH.

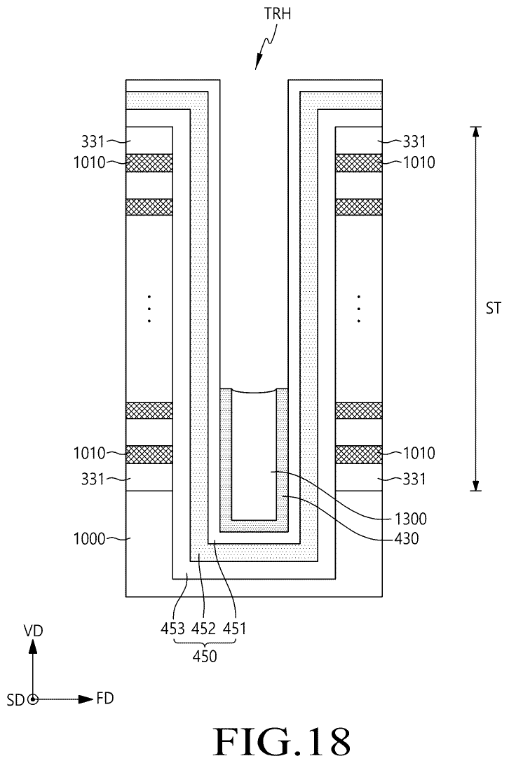

Referring to FIG. 18, a portion of the second sacrificial layer 1300 may be removed. In an embodiment, the second sacrificial layer 1300 may be removed through a wet etching process. The second sacrificial layer 1300 may be removed up to the uppermost surface of the first channel pattern 430. In an embodiment, the upper surface of the second sacrificial layer 1300 which remains by not being removed may be positioned lower than the uppermost surface of the first channel pattern 430 in the third direction VD.

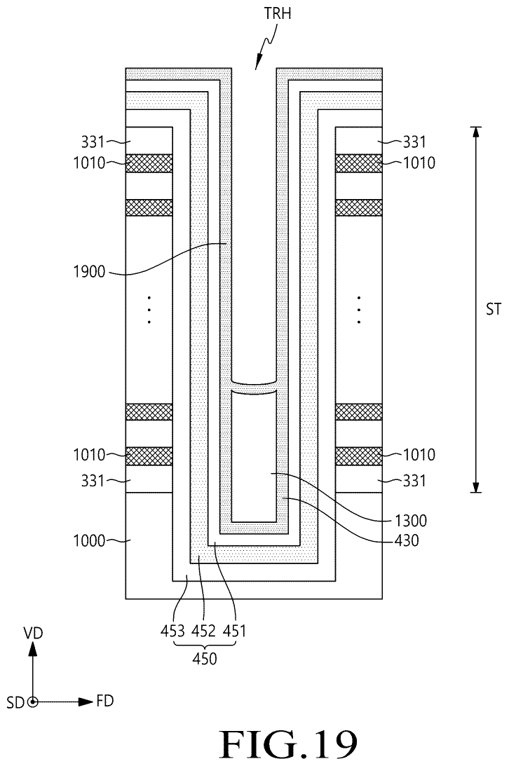

Referring to FIG. 19, a first material layer 1900 may be formed on the sidewall of the information storage structure 450, the upper surface of the second sacrificial layer 1300 and the first channel pattern 430. The width of the first material layer 1900 in the first direction FD may be the same as the width of the first channel pattern 430 in the first direction FD. The first material layer 1900 may be continuous to the first channel pattern 430. The first material layer 1900 may be made of the same material as the first channel pattern 430.

The length of the first channel pattern 430 in the third direction VD may be smaller than the length of the first material layer 1900 in the third direction VD. In an embodiment, the length of the first channel pattern 430 in the third direction VD may be equal to or smaller than ⅓ of the length of the first material layer 1900 in the third direction VD.

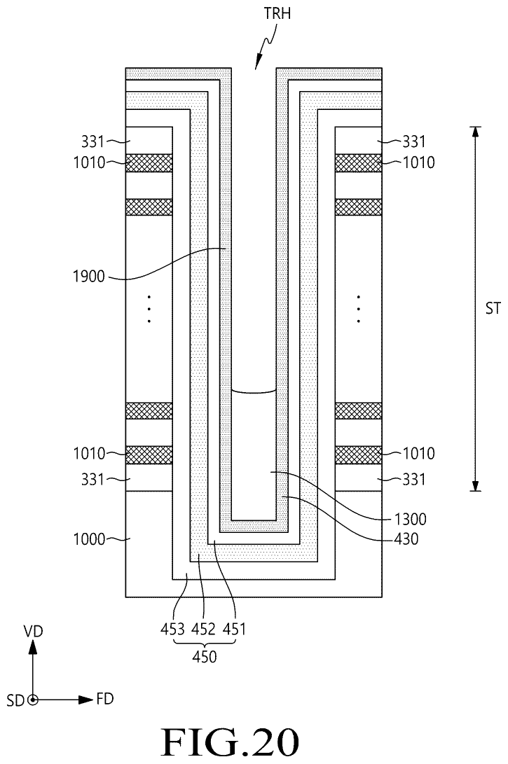

Referring to FIG. 20, a portion of the first material layer 1900 may be removed, for example, via a wet etching process. Only a portion of the first material layer 1900 which is positioned on the upper surface of the second sacrificial layer 1300 may be selectively removed. As the first material layer 1900 is removed, the upper surface of the second sacrificial layer 1300 may be exposed.

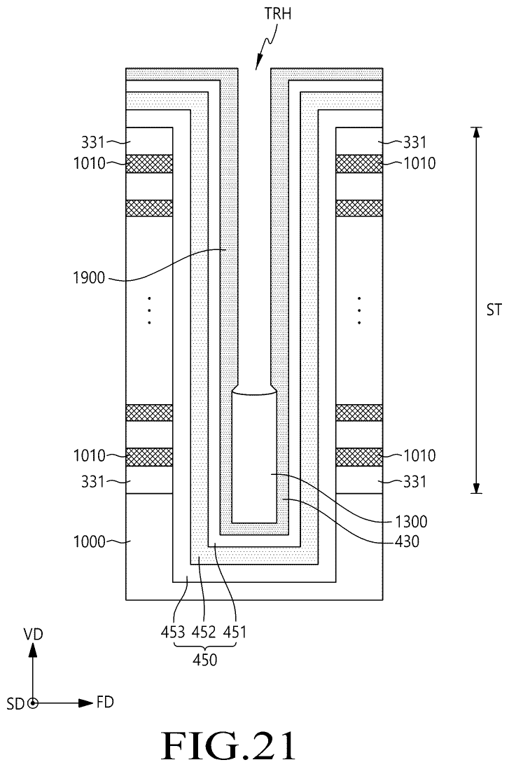

Referring to FIG. 21, a first material layer 1900 may be further formed on the sidewall of the first material layer 1900. The width of the first material layer 1900 in the first direction FD may be larger than the width of the first channel pattern 430 in the first direction FD.

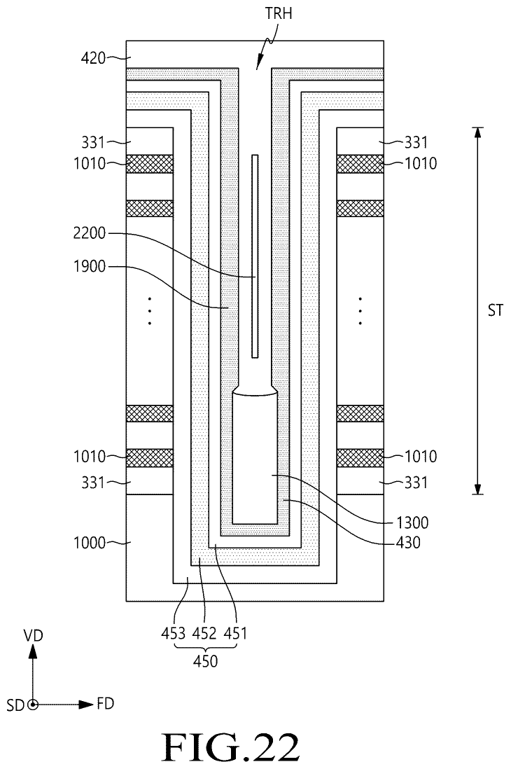

Referring to FIG. 22, a second insulating layer 420 may be formed on the sidewall of the first material layer 1900 and the exposed upper surface of the second sacrificial layer 1300. The second insulating layer 420 may fill the inside of the through hole TRH. The second insulating layer 420 may contact the sidewall of the first material layer 1900 and the upper surface of the second sacrificial layer 1300.

The second sacrificial layer 1300 may overlap with the first channel pattern 430 in the first direction FD. The second insulating layer 420 may overlap with the first material layer 1900 in the first direction FD. However, the embodiments are not limited thereto. In an embodiment, a portion of the second sacrificial layer 1300 may overlap with the first material layer 1900 in the first direction FD, or a portion of the second insulating layer 420 may overlap with the first channel pattern 430 in the first direction FD.

In an embodiment, the second insulating layer 420 may include at least one void 2200 therein. The void 2200 may extend in the third direction VD, but the embodiments are not limited thereto. The void 2200 may overlap with the first material layer 1900 in the first direction FD.

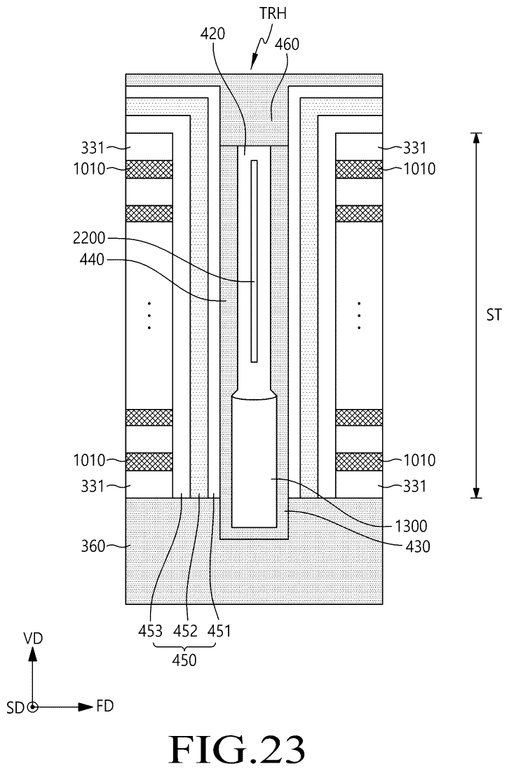

Referring to FIG. 23, a source plate 360 may be formed under the stack structure ST. The source plate 360 may directly contact the first channel pattern 430.

A drain pad 460 may be formed on the through hole TRH. A second channel pattern 440 may be formed between the drain pad 460 and the first channel pattern 430. The drain pad 460 may directly contact the second channel pattern 440.

The source plate 360, the drain pad 460, the first channel pattern 430 and the second channel pattern 440 may be formed of the same material. In an embodiment, the source plate 360, the drain pad 460, the first channel pattern 430 and the second channel pattern 440 may include a semiconductor material such as polysilicon.

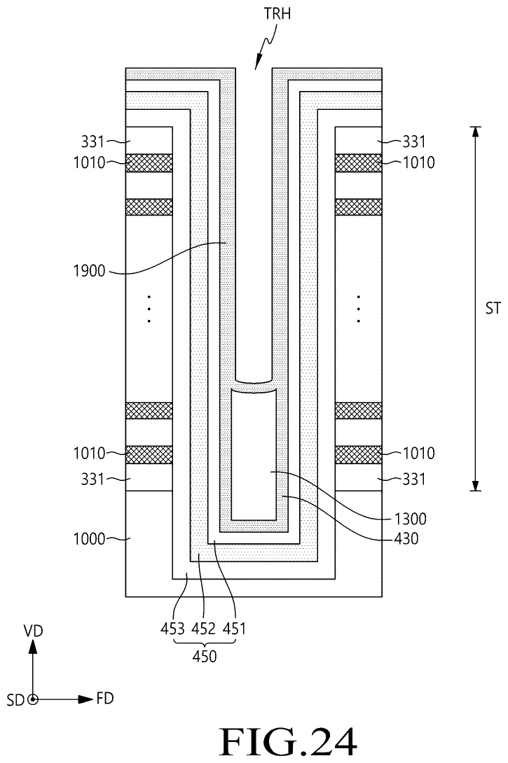

Referring to FIG. 24, a first material layer 1900 may be formed on the sidewall of the information storage structure 450, the upper surface of the second sacrificial layer 1300 and the first channel pattern 430 illustrated in FIG. 18. In an embodiment, the width of the first material layer 1900 in the first direction FD may be larger than the width of the first channel pattern 430 in the first direction FD. The first material layer 1900 may be continuous to the first channel pattern 430. The first material layer 1900 may be made of the same material as the first channel pattern 430.

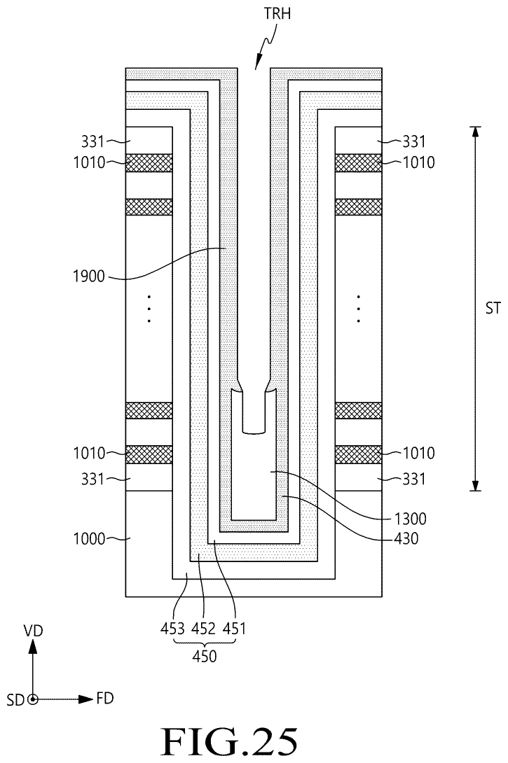

Referring to FIG. 25, a portion of the first material layer 1900 which is positioned on the upper surface of the second sacrificial layer 1300 and a portion of the second sacrificial layer 1300 may be removed. In an embodiment, the portion of the first material layer 1900 which is positioned on the upper surface of the second sacrificial layer 1300 and the portion of the second sacrificial layer 1300 may be removed by a wet etching process. As the first material layer 1900 is removed, the upper surface of the second sacrificial layer 1300 may be partially exposed. As the portion of the second sacrificial layer 1300 is removed, the second sacrificial layer 1300 may have a structure in which at least a portion of the second sacrificial layer 1300 is recessed in the third direction VD.

The same processes described above with reference to FIGS. 22 and 23 may be applied to a subsequent procedure.

Referring to FIG. 4 again, the charge storage structure 450 may be disposed on the sidewall of the through hole TRH which passes through the stack structure ST. The first channel pattern 430 may be disposed in an area adjacent to the source plate 360 on the sidewall of the charge storage structure 450. The second channel pattern 440 may be disposed on the sidewall of the charge storage structure 450 and on the first channel pattern 430 in the third direction VD.

The width of the second channel pattern 440 in the first direction FD may be different from the width of the first channel pattern 430 in the first direction FD.

According to the embodiments of the present disclosure, a channel pattern which is formed in the through hole TRH passing through the stack structure ST may include the first channel pattern 430 and the second channel pattern 440 which have different widths in the first direction FD. Since a memory device has a dual channel thickness in one through hole TRH as described above, even when the height of the stack structure ST is increased so that the length of the through hole TRH in the third direction VD increases, it is possible to prevent a channel pattern from being completely buried due to a defect in processing in an area adjacent to the source plate 360. Therefore, it is possible to prevent resultant deterioration of the characteristics of the memory device.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. The spirit and scope of the present disclosure should be interpreted in connection with the appended claims and encompass all equivalents falling within the scope of the appended claims. Furthermore, the embodiments may be combined to form additional embodiments.

What is claimed is:

1. A memory device comprising:
a source plate;
a stack structure including a plurality of interlayer insulating layers and a plurality of electrode layers which are alternately stacked on the source plate in a vertical direction;
a through hole passing through the stack structure;
a charge storage structure disposed on a sidewall of the through hole; and
a channel pattern disposed on the charge storage structure, and including a first channel pattern which is adjacent to the source plate and a second channel pattern which is disposed on the first channel pattern in the vertical direction and has a width different from a width of the first channel pattern.

2. The memory device according to claim 1, wherein the width of the first channel pattern is smaller than the width of the second channel pattern.

3. The memory device according to claim 1, wherein the first channel pattern is continuous to the second channel pattern.

4. The memory device according to claim 1, wherein a length of the first channel pattern in the vertical direction is different from a length of the second channel pattern in the vertical direction.

5. The memory device according to claim 4, wherein the length of the first channel pattern in the vertical direction is smaller than the length of the second channel pattern in the vertical direction.

6. The memory device according to claim 1, wherein a diameter of the through hole gradually increases from a lower portion to an upper portion of the through hole.

7. The memory device according to claim 1, further comprising:
a first insulating layer disposed on a sidewall of the first channel pattern, and filling the through hole; and
a second insulating layer disposed on a sidewall of the second channel pattern, and filling the through hole,
wherein a material of which the first insulating layer is made is different from a material of which the second insulating layer is made.

8. The memory device according to claim 7, wherein the second insulating layer includes at least partially a void therein.

9. The memory device according to claim 7, wherein each of the first insulating layer and the second insulating layer includes one of silicon oxide, silicon nitride, silicon oxynitride, polysilicon or a combination thereof.

10. The memory device according to claim 1,
wherein the plurality of electrode layers comprise:
at least one source select line adjacent to the lower portion of the through hole;
at least one drain select line adjacent to the upper portion of the through hole;
a plurality of word lines between the at least one source select line and the at least one drain select line; and
at least one dummy electrode line between the at least one source selection line and a word line, and
wherein the at least one dummy electrode line overlaps at least one of the first channel pattern and the second channel pattern.

11. The memory device according to claim 10, wherein the at least one dummy electrode line overlaps the first channel pattern.

12. The memory device according to claim 10, wherein the at least one dummy electrode line overlaps the second channel pattern.

13. The memory device according to claim 11, wherein at least one of the plurality of word lines overlaps the first channel pattern.

14. The memory device according to claim 12, wherein the plurality of word lines are disposed in an area excluding an area which overlaps the first channel pattern.

15. The memory device according to claim 1, wherein the width of the first channel pattern is larger than the width of the second channel pattern.

16. A memory device comprising:
a source plate;
a stack structure including a plurality of interlayer insulating layers and a plurality of electrode layers which are alternately stacked on the source plate in a vertical direction;
a through hole passing through the stack structure;
a charge storage structure disposed on a sidewall of the through hole;
a channel pattern disposed on the charge storage structure, and including a first channel pattern which is adjacent to the source plate and a second channel pattern which is disposed on the first channel pattern in the vertical direction;
a first insulating layer disposed on a sidewall of the first channel pattern, and filling the through hole; and
a second insulating layer disposed on a sidewall of the second channel pattern, filling the through hole, and having a width of at least a portion thereof smaller than a width of the first insulating layer.

17. The memory device according to claim 16, wherein a material of which the first insulating layer is made is different from a material of which the second insulating layer is made.

18. The memory device according to claim 16, wherein
the through hole extends into the source plate, and
the first insulating layer fills a portion of the through hole which extends into the source plate.

19. A method of forming a memory device, the method comprising:
forming, on a substrate, a stack structure in which a plurality of interlayer insulating layers and a plurality of sacrificial layers are alternately stacked in a direction perpendicular to the substrate;
forming a through hole which passes through the stack structure;
forming a first channel pattern along a sidewall of the through hole;
etching at least a portion of the first channel pattern; and
forming a second channel pattern which has a width different from the first channel pattern, on the first channel pattern along a sidewall of the through hole in a vertical direction.

20. The method according to claim 19, further comprising:
forming a first insulating layer which is disposed on a sidewall of the first channel pattern and fills the through hole, after forming the first channel pattern; and
forming a second insulating layer which is disposed on a sidewall of the second channel pattern and fills the through hole, after forming the second channel pattern.
